(19) United States
(12) Patent Application Publication
(10) Pub. No.: US 2023/0145507 A1
(43) Pub. Date: May 11, 2023

(54) ELECTRONIC COMPONENT MOUNTING METHOD AND ELECTRONIC COMPONENT

(71) Applicant: JAPAN AVIATION ELECTRONICS INDUSTRY, LIMITED, Tokyo (JP)

(72) Inventor: Osamu HASHIGUCHI, Tokyo (JP)

(73) Assignee: JAPAN AVIATION ELECTRONICS INDUSTRY, LIMITED, Tokyo (JP)

(21) Appl. No.: 17/958,635

(22) Filed: Oct. 3, 2022

(30) Foreign Application Priority Data
Nov. 5, 2021 (JP) 2021-180925

(51) Int. Cl. H05K 3/30; H05K 3/34; H05K 3/12

(52) U.S. Cl. CPC H05K 3/303; H05K 3/3494; H05K 3/3421; H05K 3/1283; H05K 3/12

(57) ABSTRACT

A connector includes lead parts and terminal parts to be connected to lands of a substrate, respectively. An anisotropic conductive joining member (ACJM) is mounted in a region where the lead parts are located. The ACJM is a resin in which solder particles are dispersed. The resin can melt at a temperature lower than the melting point of the solder particles. Cream solder is placed on the lands to be connected to the terminal parts. The substrate on which the connector is mounted is passed through a reflow oven to heat both the substrate and the connector. The connection between the terminal parts and the lands by reflow soldering and the connection between the lead parts and the lands via the ACJM 40 are performed simultaneously with each other.

### TECHNICAL FIELD

The present invention relates to an electronic component to be surface-mounted on a substrate and a mounting method therefor.

### BACKGROUND ART

Examples of a method for surface-mounting an electronic component on a substrate include a method based on reflow soldering, and a method based on thermocompression using ACF (Anisotropic Conductive Film), and Japanese Patent Application Laid-Open No. 2002-314236 (hereinafter referred to as Patent Literature 1) discloses that a chip component which is an electronic component is mounted by soldering, and an IC chip which is an electronic component is mounted by thermocompression using ACF.

FIG. 1 shows a flowchart showing a process of an electronic component mounting method described in Patent Literature 1, which first performs a reflow soldering process Pa, and then performs a thermocompression process Pb.

In the reflow soldering process Pa, solder is printed on terminals in a chip component mounting region of a substrate (step P1), and electronic components (chip components) such as an electrolytic capacitor are mounted on the terminals (step P2). Next, the substrate on which the electronic components are placed is transferred into a reflow oven, and hot air is supplied to the substrate in the reflow oven (step P3). As a result, the solder melts and the electronic components are soldered.

When the reflow soldering process Pa is completed, the processing proceeds to the thermocompression process Pb. In the thermocompression process Pb, ACF is first attached, that is, placed in an IC chip mounting region of the substrate (step P4). After the ACF is attached, an IC chip is mounted (step P5), and then the IC chip is pressed against the substrate by a heated head (step P6). As a result, the entire IC chip is caused to adhere to the surface of the substrate by the resin of ACF, and bumps of the IC chip are conductively connected to corresponding leads of the substrate by conductive particles of ACF.

As described above, in Patent Literature 1, various electronic components are surface-mounted on the substrate by sequentially performing both the reflow soldering process Pa and the thermocompression process Pb of ACF.

As in the case where ACF is used for mounting an IC chip in Patent Literature 1 described above, the connection using ACF makes it possible to connect a large number of electrodes at one time and make fine connections excellently. Therefore, it is desirable to use ACF when a minute connector having a large number of contacts arranged at a narrow pitch (fine pitch) is surface-mounted on a substrate.

On the other hand, a connector suffers an external force when it is inserted into and removed from a mating connector, and thus if the connector is mounted on the substrate with being joined to the substrate by only ACF, there is a risk that exfoliation may occur at a joint part due to external force because the joining strength of ACF is weak. Therefore, when ACF is used for mounting a connector on a substrate in this way, it is preferable that a reinforcing metal fitting is provided to the connector, and the reinforcing metal fitting is soldered to the substrate to secure the joining strength between the connector and the substrate, that is, the attaching strength of the connector to the substrate, for example.

Here, if a reinforcing metal fitting is provided to such a minute connector, a terminal part of the reinforcing metal fitting to be soldered to the substrate and a lead part of the contact to be connected to the substrate via ACF must be close to each other, that is, a land on the substrate to which the terminal part of the reinforcing metal fitting is connected and a land on the substrate to which the lead part of the contact is connected are close to each other. Therefore, when ACF is mounted on such a substrate, it is necessary to perform positioning with high accuracy so that ACF is located only on a predetermined land (land group). For example, high positioning accuracy such as ±0.05 mm is required depending on the specifications of connectors.

In order to mount ACF on a substrate with such high positioning accuracy, for example, in a series of steps and facilities of a general automatic assembly machine for performing surface-mounting of electronic components on a substrate by printing cream solder on the substrate, mounting electronic components on the substrate, and passing the substrate through a reflow oven, it is necessary to change the facilities or add facilities, and it has taken a high cost to change or add facilities in a general large-scale automatic assembly machine for performing surface-mounting of electronic components on a substrate.

### BRIEF SUMMARY OF THE INVENTION

In view of such circumstances, an objective of the present invention is to provide an electronic component to be surface-mounted on a substrate, the electronic component comprising a connection part to be connected via an anisotropic conductive joining member and a connection part to be connected by solder, and being improved to suppress an increase in equipment cost caused by use of the anisotropic conductive joining member, and further to provide a simple mounting method of such an electronic component.

The following technical matters in this section are described simply to facilitate the understanding of the main points of the present invention, not to limit the invention claimed in the claims explicitly or implicitly and not to express the possibility of accepting such a limitation that is imposed by a person other than those who will benefit from the present invention (for example, the applicant and the right holder). The general outline of the present invention described from other perspectives can be understood from, for example, the claims of this application as originally filed at the time of application.

An electronic component automatic assembly machine having a high-accuracy positioning mechanism is used to position an anisotropic conductive joining member with respect to an electronic component with high accuracy, and attach the anisotropic conductive joining member to the electronic component. The electronic component to which the anisotropic conductive joining member is attached is subjected to a reflow process. In the reflow process, joint using the cream solder and joint using the anisotropic conductive joining member are performed at the same time.

These and other objects, features and advantages of the present invention will become apparent from the detailed description taken in conjunction with the accompanying drawings.

### Effects of the Invention

According to the present invention, surface-mounting an electronic component comprising a connection part to be connected via an anisotropic joining member and a connection part to be connected by solder can be simply performed on a substrate while suppressing an increase in equipment cost caused by use of the anisotropic conductive joining member.

### BRIEF DESCRIPTION OF THE DRAWINGS

The subject matter, which is regarded as the invention, is particularly pointed out and distinctly claimed in the claims at the conclusion of the specification. The present invention itself, and manner in which it may be made or used, if any, may be better understood after a review of the following description in connection with the accompanying drawings in which:

FIG. 1 is a process diagram showing a conventional example of a method for mounting an electronic component;

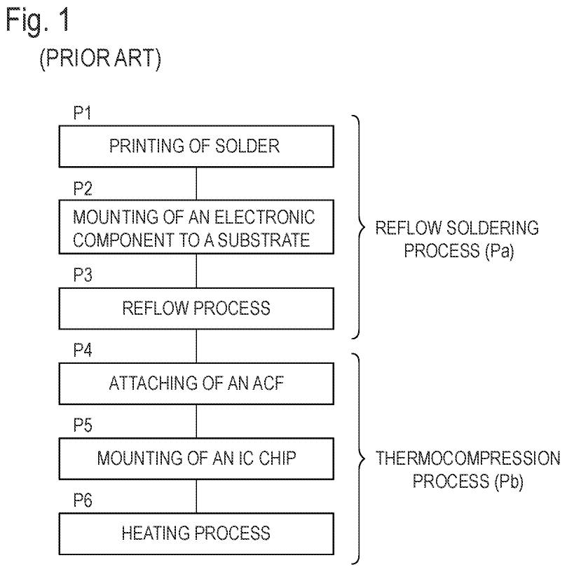

FIG. 2A is a partially exploded perspective view of an embodiment of an electronic component according to the present invention, which is viewed from an upper side of the electronic component;

FIG. 2B is a partially exploded perspective view of the embodiment of the electronic component according to the present invention, which is viewed from a lower side of the electronic component;

FIG. 3A is a perspective view showing the embodiment of the electronic component according to the present invention, which is viewed from the upper side of the electronic component;

FIG. 3B is a perspective view of the electronic component shown in FIG. 3A, which is viewed from the lower side of the electronic component;

FIG. 4 is a perspective view showing an outline of a substrate on which the electronic component shown in FIG. 3A is surface-mounted;

FIG. 5 is a perspective view showing an aspect in which the electronic component shown in FIG. 3A is mounted on the substrate;

FIG. 6 is a perspective view showing a state in which the electronic component shown in FIG. 3A is mounted on the substrate; and

FIG. 7 is a process diagram of a method for mounting an electronic component according to an embodiment.

### LIST OF REFERENCE NUMERALS

With regard to reference numerals used, the following numbering is used throughout the drawings.
10: housing
20: contact
21: lead part
30: reinforcing metal fitting
31: upper plate part
32: terminal part
40: anisotropic conductive joining member
100: connector
200: substrate
210: land
220: land
230: cream solder

### DETAILED DESCRIPTION

An embodiment of the present invention will be described by way of examples with reference to the drawings.

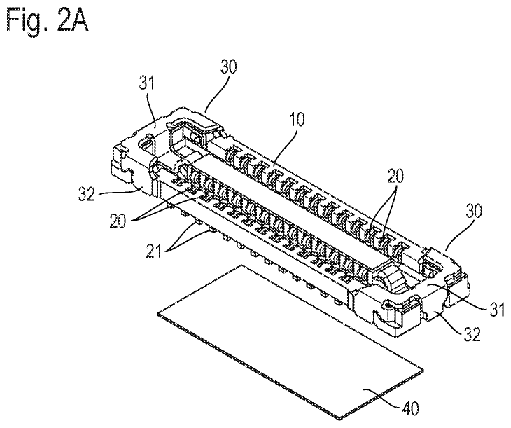

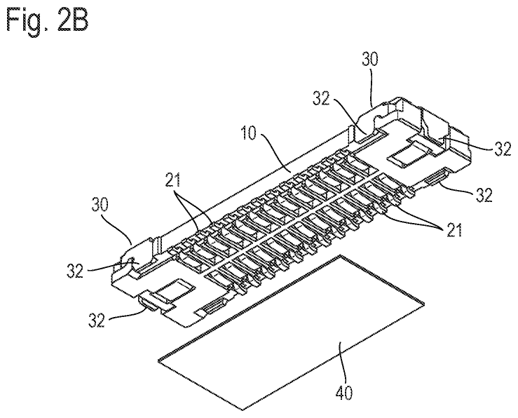

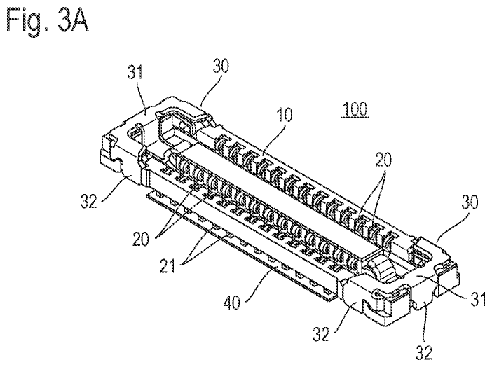

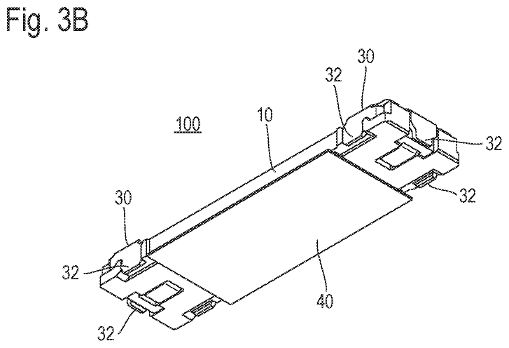

FIGS. 2A, 2B, 3A, and 3B show a connector as an example of an electronic component according to the present invention to be surface-mounted on a substrate, FIGS. 2A and 2B are partially exploded diagrams thereof, and FIGS. 3A and 3B show a finished product.

In this example, the connector 100 is composed of a resin housing 10, a large number of contacts 20 arranged and held in the housing 10, a pair of reinforcing metal fittings 30, and an anisotropic conductive joining member 40.

A housing 10 has a flat, elongated and substantially rectangular parallelepiped shape, and in this example, contacts 20 are arranged in the housing 10 in two rows, each row including thirteen contacts, and totally twenty six contacts are attached. Lead parts 21 of the contacts 20 to be connected to lands on the substrate are located on the lower surface side of the housing 10.

A pair of reinforcing metal fittings 30 are attached to both end parts in the longitudinal direction of the housing 10, and each of these reinforcing metal fittings 30 includes an upper plate part 31 located so as to cover the top surface of an end part in the longitudinal direction of the housing 10, and terminal parts 32 which are bent and extended from the upper plate part 31 along the side surface of the housing 10 and reaches the lower surface of the housing 10. In this example, the terminal parts 32 are provided at three locations of one reinforcing metal fitting 30.

In this example, the anisotropic conductive joining member 40 is formed by dispersing solder particles in resin and has a rectangular film shape. The resin constituting the anisotropic conductive joining member 40 may be a thermoplastic resin or a thermosetting resin, which is melted at a temperature lower than the melting point of the solder particles.

At a low temperature and under a low pressure, the anisotropic conductive joining member 40 is attached to the lower surface of the housing 10 in a region where the lead parts 21 of the twenty six contacts 20 are located, and is mounted as shown in FIGS. 3A and 3B.

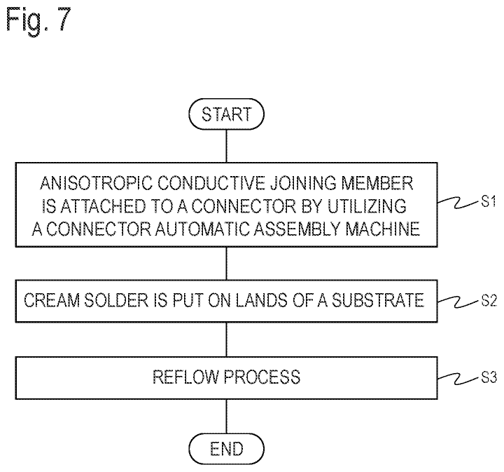

In this example, as described above, the connector 100 comprises the anisotropic conductive joining member 40, and the connector is generally assembled by an automatic assembly machine. An automatic assembly machine for assembling a fine connector having a large number of contacts arranged at a narrow pitch includes a high-accuracy positioning mechanism. Therefore, the anisotropic conductive joining member 40 can be positioned and mounted with high accuracy by using the above automatic assembly machine. In other words, a step of installing an anisotropic conductive joining member 40 into an automatic assembly machine for assembling a connector (step S1; FIG. 7) may be merely incorporated. In this respect, the change of facilities may be a little, and the cost may also be low.

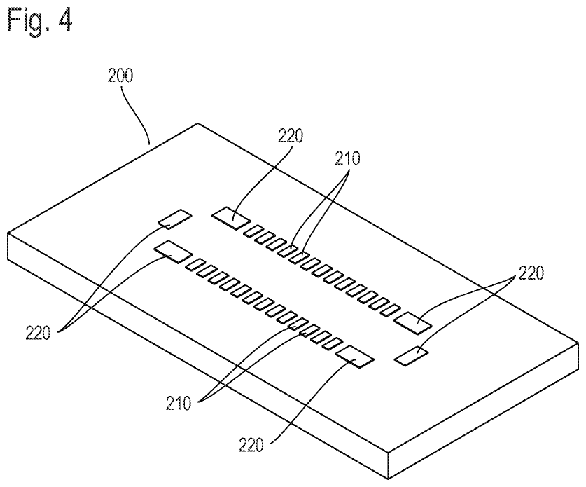

FIG. 4 shows a substrate 200 on which the connector 100 described above will be surface-mounted, and FIG. 4 shows only a portion of the substrate 200 where the connector 100 is surface-mounted, and omits illustration of the other portions.

Twenty six lands 210 are formed on the surface of the substrate 200 in connection with the lead parts 21 of the twenty six contacts 20 of the connector 100, and further six lands 220 are formed in connection with the totally six terminal parts 32 of the pair of reinforcing metal fittings 30.

A method for surface-mounting the connector 100 on the substrate 200 will be hereunder described.

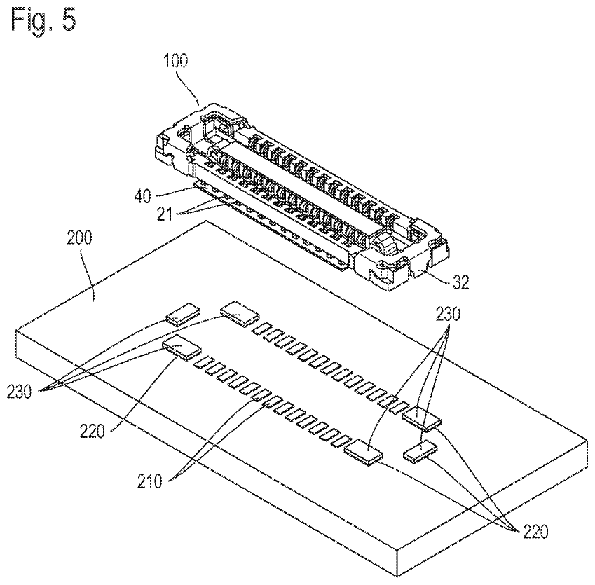

First, cream solder is printed and coated onto the lands 220 of the substrate 200 to which the terminal parts 32 of the reinforcing metal fittings 30 of the connector 100 will be connected, whereby cream solder 230 is placed on the lands 220 as shown in FIG. 5 (step S2; FIG. 7).

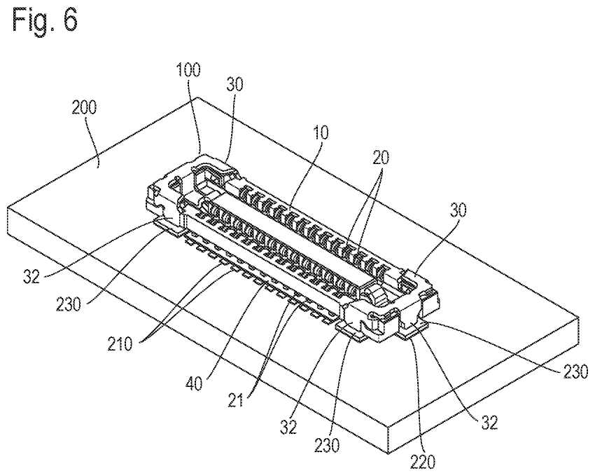

Next, the connector 100 is positioned and mounted on the substrate 200 as shown in FIG. 6, passed through a reflow oven, and heated (step S3; FIG. 7). As a result, the cream solder is melted, and the terminal parts 32 of the reinforcing metal fittings 30 of the connector 100 are connected to the corresponding lands 220 of the substrate 200 by the solder. Further, the resin of the anisotropic conductive joining member 40 is melted, and the solder particles are melted, so that the lead parts 21 of the contacts 20 of the connector 100 are connected to the corresponding lands 210 of the substrate 200 by the melted solder particles.

As described above, in this example, one reflow process simultaneously performs the connection between the terminal parts 32 of the reinforcing metal fittings 30 and the lands 220 of the substrate 200 by reflow soldering and the connection between the lead parts 21 of the contacts 20 and the lands 210 of the substrate 200 via the anisotropic conductive joining member 40. Note that the anisotropic conductive joining member 40 implements joining by melting the resin and the solder particles thereof, so that pressurization is unnecessary and joining can be performed without any load.

In the above-mentioned example, the anisotropic conductive joining member uses a material in which solder particles are dispersed in resin. However, the present invention is not limited to this type, and a thermocompression type in which nickel particles or the like are dispersed in resin and heating and pressurization are necessary may be used. In this case, in step S3, the connector may be passed through the reflow oven and heated in a state where the connector is pressed against the substrate by a press jig to pressurize the anisotropic conductive joining member, so that even a thermocompression type anisotropic conductive joining member can implement joining in the reflow process.

The electronic component and the method for mounting the electronic component according to the present invention has been described above by using a connector as an example. However, the electronic component is not limited to the connector, but any member may be used insofar as it is surface-mounted on a substrate and has a first connection part to be connected to a land on the substrate via an anisotropic conductive joining member and a second connection part to be connected to a land on the substrate by soldering. In the connector 100 described above, the lead part 21 of the contact 20 serves as the first connection part, and the terminal part 32 of the reinforcing metal fitting 30 serves as the second connection part. In the connector 100, the reinforcing metal fitting 30 is soldered to the substrate 200 in order to secure the mounting strength (joining strength) to the substrate 200, but another example of the second connection part needing soldering is a terminal for large current or the like.

Further, with respect to the anisotropic conductive joining member to be arranged in the region where the first connection parts are located, in the above-mentioned example, a film-shaped member is attached and mounted, but for example, a paste-like member may be coated and shaped like a film.

Addendum

While the invention has been described with reference to exemplary embodiments, it will be understood by those skilled in the art that various changes may be made and equivalents may be substituted for elements thereof without departing from the scope of the invention. In addition, many modifications may be made to adapt a particular system, device or component thereof to the teachings of the invention without departing from the essential scope thereof. Therefore, it is intended that the invention not be limited to the particular embodiments disclosed for carrying out this invention, but that the invention will include all embodiments falling within the scope of the appended claims.

Moreover, the use of the terms “first”, “second”, “i-th”, etc., if any, do not denote any order or importance, but rather the terms “first”, “second”, “i-th”, etc. are used to distinguish one element from another. The term “first” does not necessarily mean “coming before all others in order”. The terminology used herein is for the purpose of describing particular embodiments only and is not intended to limit the invention in any way. As used herein, the singular forms “a”, “an” and “the” are intended to include the plural forms as well, unless the context clearly indicates otherwise. It will be further understood that the terms “comprise”, “comprises”, and/or “comprising,” when used in this specification and/or the appended claims, specify the presence of stated features, steps, operations, elements, and/or components, but do not preclude the presence or addition of one or more other features, steps, operations, elements, components, and/or groups thereof. The same goes for “include”, “includes”, and/or “including”. The term “and/or”, if any, includes any and all combinations of one or more of the associated listed items. In the claims and the specification, unless otherwise noted, “connect”, “join”, “couple”, “interlock”, or synonyms therefor and all the word forms thereof, if any, do not necessarily deny the presence of one or more intermediate elements between two elements, for instance, two elements “connected” or “joined” to each other or “interlocked” with each other. Connection between elements, if required, may be physical connection, electrical connection, or a combination thereof.

Unless otherwise defined, all terms (including technical and scientific terms) used herein have the same meaning as commonly understood by those skilled in the art to which the invention belongs. It will be further understood that terms, such as those defined in commonly used dictionaries, should be interpreted as having a meaning that is consistent with their meaning in the context of the relevant art and the present disclosure and will not be interpreted in an idealized or overly formal sense unless expressly so defined herein.

In describing the invention, it will be understood that a number of techniques and steps are disclosed. Each of these has individual benefit and each can also be used in conjunction with one or more, or in some cases all, of the other disclosed techniques. Accordingly, for the sake of clarity, this description will refrain from repeating every possible combination of the individual techniques or steps in an unnecessary fashion. Nevertheless, the specification and claims should be read with the understanding that such combinations are entirely within the scope of the invention and the claims.

The corresponding structures, materials, acts, and equivalents of all means or step plus function elements in the claims below, if any, are intended to include any structure, material, or act for performing the function in combination with other claimed elements as specifically claimed.

The foregoing description of the embodiments of the invention has been presented for the purpose of illustration and description. It is not intended to be exhaustive and to limit the invention to the precise form disclosed. Modifications or variations are possible in light of the above teaching. The embodiments were chosen and described to provide the best illustration of the principles of the invention and its practical application, and to enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly, legally, and equitably entitled.

What is claimed is:

1. A method for mounting an electronic component on a substrate, the electronic component comprising a first connection part and a second connection part to be respectively connected to lands on the substrate, and an anisotropic conductive joining member mounted in a region where the first connection part is located, the anisotropic conductive joining member having a resin where solder particles are dispersed, the resin being configured to melt at a temperature lower than a melting point of the solder particles, the method comprising:
printing cream solder onto a land of the substrate to be connected to the second connection part; and
mounting the electronic component on the substrate, and passing the substrate with the electronic component mounted through a reflow oven to heat the substrate with the electronic component mounted, thereby simultaneously performing connection between the second connection part and the land on the substrate by reflow soldering, and connection between the first connection part and a land on the substrate via the anisotropic conductive joining member.

2. A method for mounting an electronic component on a substrate, the electronic component comprising a first connection part and a second connection part to be respectively connected to lands on the substrate, and an anisotropic conductive joining member mounted in a region where the first connection part is located, the method comprising:
printing cream solder onto a land of the substrate to be connected to the second connection part; and
mounting the electronic component on the substrate, and passing the substrate with the electronic component mounted through a reflow oven to heat the substrate with the electronic component mounted in a state where the electronic component is pressed against the substrate by a press jig, thereby simultaneously performing connection between the second connection part and the land on the substrate by reflow soldering, and connection between the first connection part and a land on the substrate by thermocompression of the anisotropic conductive joining member.

3. The method according to claim 1, wherein the electronic component is a connector comprising a housing; contacts arranged and held in the housing; and a reinforcing metal fitting attached to the housing, the first connection part comprises lead parts of the contacts, and the second connection part comprises a terminal part of the reinforcing metal fitting.

4. The method according to claim 2, wherein the electronic component is a connector comprising a housing; contacts arranged and held in the housing; and a reinforcing metal fitting attached to the housing, the first connection part comprises lead parts of the contacts, and the second connection part comprises a terminal part of the reinforcing metal fitting.

5. An electronic component to be surface-mounted on a substrate, comprising a first connection part and a second connection part to be respectively connected to lands on the substrate, wherein the first connection part is to be connected via an anisotropic conductive joining member, the second connection part is to be connected by solder, and the anisotropic conductive joining member is mounted in a region where the first connection part is located.

6. The electronic component according to claim 5, wherein the anisotropic conductive joining member has a resin where solder particles are dispersed, and the resin is configured to melt at a temperature lower than a melting point of the solder particles.

7. The electronic component according to claim 5, wherein the electronic component is a connector comprising a housing; contacts arranged and held in the housing; and a reinforcing metal fitting attached to the housing, the first connection part comprises lead parts of the contacts, and the second connection part comprises a terminal part of the reinforcing metal fitting.

8. The electronic component according to claim 6, wherein the electronic component is a connector comprising a housing; contacts arranged and held in the housing; and a reinforcing metal fitting attached to the housing, the first connection part comprises lead parts of the contacts, and the second connection part comprises a terminal part of the reinforcing metal fitting.
